(19) United States
(12) Patent Application Publication
(10) Pub. No.: US 2008/0211519 A1
(43) Pub. Date: Sep. 4, 2008

(54) CAPACITANCE SENSOR

(75) Inventors: Yukinori Kurumado, Ogaki-city (JP); Keiichi Nagayama, Aichi-gun (JP); Masato Kasashima, Kasugai-city (JP); Hiroyuki Sueyasu, Kasugai-city (JP); Ryuichi Nakano, Wako-shi (JP); Taizo Kikuchi, Wako-shi (JP)

Correspondence Address: OSHA LIANG L.L.P., 1221 MCKINNEY STREET, SUITE 2800, HOUSTON, TX, 77010, US

(73) Assignees: OMRON CORPORATION, Kyoto-shi (JP); HONDA MOTOR CO., LTD., Tokyo (JP)

(21) Appl. No.: 12/034,522

(22) Filed: Feb. 20, 2008

(30) Foreign Application Priority Data
Feb. 20, 2007 (JP) 2007-038739

(51) Int. Cl. G01R 27/26

(52) U.S. Cl. 324/688

(57) ABSTRACT

A code-type sensor for detecting a change in capacitance includes a plurality of detection electrodes for detecting a change in capacitance, a shield electrode surrounding the plurality of detection electrodes so as to restrict a detection range of the capacitance and having an opening in a direction of detection, and a contact detecting electrode for detecting contact disposed along a longitudinal direction of the sensor. The detection electrodes are disposed at a position close to the opening in the shield electrode and at a position far from the opening in the shield electrode. The contact detecting electrode is disposed on a back side in the direction of detection of the shield electrode. The respective detection electrodes are integrally connected to each other in such a way as to be held in a separate state, the detection electrodes and the shield electrode are integrally connected to each other in such a way as to be held in a separate state, and the shield electrode and the contact detecting electrode are kept in such a way as to be held in a separate state across a clearance in a natural state and are brought into contact with each other when the sensor is pressed in the direction of detection by contact of an object.

### BACKGROUND OF THE INVENTION

1. Field of the Invention

The present invention relates to a capacitance sensor, more specifically to a capacitance sensor for detecting a man or an object so as to prevent the man or the object from being caught by an opening/closing body such as a door.

2. Description of Related Art

In a control system of an opening/closing body such as a door, in order to prevent the opening/closing body from catching a human body or the like, the control system is provided with a catch preventing function that detects the opening/closing body catching or likely to catch the human body or the like at the time of performing an automatic closing operation and at least stops the automatic closing operation of the opening/closing body or further reverses the automatic closing operation.

A system of a detection device for detecting and preventing a catch includes an indirect detection system and a direct detection system. The indirect detection system detects a catch indirectly on the basis of the operating information (rotational position and rotational speed) of a drive motor of an opening/closing body, and the direct detection system uses a sensor for detecting an object (such as a human body) that approaches or comes into contact with an opening/closing edge portion of the opening/closing body. Of these systems, the indirect detection system has disadvantages in that it is difficult for the indirect detection system to detect a catch as early or as reliably as the direct detection system or to detect a catch with as low a load. On the other hand, the direct detection system has advantages in that the direct detection system detects the object directly and hence has high reliability. A pressure-sensitive switch has been used as a sensor of this kind, so that it is impossible for the sensor to detect a catch of a lower load or to detect the catch earlier. This is because the pressure-sensitive switch is shaped like a cable using conductive resin, for example, and has its internal conductors deformed and brought into conduction by the pressure of the object, which activates the switch. For this reason, the switch is activated and a catch preventing function is brought into operation only after the object comes into contact with the pressure sensitive switch at a certain level of pressure.

Thus, the inventors have conducted a study of basically applying a capacitance sensor as a catch detecting device in a power sliding door or the like of a vehicle.

In this regard, an example in the related art of applying a capacitance sensor as a catch detecting device in a power sliding door of a vehicle (four-wheel automobile and the like) is JP-A-2005-227244 (patent document 2). Further, JP-A-2001-32628 (patent document 1) discloses a catch preventing device using a capacitance sensor for detecting a catch by a window or a door. Further, JP-A-2001-32627 (patent document 3) discloses a safety device for an automatic door that detects a catch by a capacitance sensor.

When the above-mentioned capacitance sensor is applied to an opening/closing body such as a sliding door or the like of a vehicle so as to detect an object being caught, the capacitance sensor reacts to the peripheral parts (for example, the B pillar and front door of the vehicle) of the opening/closing body near a totally closed position where the opening/closing body is totally closed, which changes the output of the capacitance sensor (hereinafter referred to as a “sensor output” in some cases). This presents a problem that, although a human body or the like is not actually caught, the sensor falsely detects the human body or the like as being caught.

Here, the sliding door is a sliding type door mounted on the side or the like of a vehicle, and in the case of a four-wheel automobile, the sliding door is mounted as a door for rear seats (rear door) in many cases.

In this regard, the above-mentioned patent document 3 discloses the technology of setting an allowable value (threshold value for detection determination) on the basis of, for example, a sensor output (that is, learned data) measured when an automatic door is operated in an opening direction and comparing the sensor output with the allowable value to determine a catch when the automatic door is operated in a closing direction, and further discloses the technology of gradually changing the allowable value on the basis of the learned data near a position where the door is totally closed. According to these technologies, in principle, the effects of the above-mentioned peripheral parts can be canceled by a change in the allowable value, and hence the possibility of the above-mentioned false detection occurring near the position where the opening/closing body is totally closed can be reduced.

However, with these technologies, near the position where the door is totally closed, the sensor output is greatly affected by even a small change in the position of the door, so that it is difficult to acquire a small change in the sensor output caused by an approaching finger or the like.

Further, the capacitance sensor does not react to an object other than a dielectric object and hence has difficulty in detecting a low dielectric material such as plastic. The capacitance sensor also has a drawback such that the capacitance sensor has difficulty in preventing, for example, an article made of plastic to be carried into a vehicle from being caught by the sliding door.

In this regard, the above-mentioned problems (the problem that the capacitance sensor has difficulty in detecting the object at the totally closed position, and the problem that the capacitance sensor cannot detect a low dielectric object) are important for a sensor of a safety device for preventing an opening/closing body from catching an object and hence need to be solved in earnest.

### SUMMARY OF THE INVENTION

The present invention provides a capacitance sensor that effects an essential function as a proximity sensor (non-contact sensor) of a capacitance type and functions also as a contact type sensor (touch sensor) for detecting contact of a man or an object.

A capacitance sensor of the present invention is a code-type sensor for detecting a change in capacitance which includes:

a plurality of detection electrodes for detecting a change in capacitance, a shield electrode surrounding the plurality of detection electrodes so as to restrict a detection range of the capacitance and having an opening in a direction of detection, and a contact detecting electrode for detecting contact disposed along a longitudinal direction of the sensor, wherein

the detection electrodes are disposed at a position close to the opening in the shield electrode and at a position far from the opening in the shield electrode,

the contact detecting electrode is disposed on a back side in the direction of detection of the shield electrode, and

the respective detection electrodes are integrally connected to each other in such a way as to be held in a separate state, the detection electrodes and the shield electrode are integrally connected to each other in such a way as to be held in a separate state, and the shield electrode and the contact detecting electrode are kept in such a way as to be held in a separate state across a clearance in a natural state and are brought into contact with each other when the sensor is pressed in the direction of detection by contact of an object.

According to one or more embodiments of the capacitance sensor of the present invention, a change in the capacitance (approach of a dielectric object) can be detected at high sensitivity by a difference mode and hence a dielectric object such as a human body can be quickly detected in a non-contact manner. Further, according to one or more embodiments of the present invention, since the capacitance sensor has the shield electrode, the capacitance sensor can detect only a dielectric object approaching in the direction of detection (opening side of the shield electrode) and hence does not falsely detect a dielectric object approaching from the side.

In addition, according to one or more embodiments of the present invention, when the capacitance sensor is pressed in the direction of detection by the contact of the object, the shield electrode and the contact detecting electrode come into contact with each other, whereby the contact of the object can be detected. For this reason, the capacitance sensor functions also as a touch sensor for detecting the contact of the object.

One or more embodiments of the present invention provide a construction in which the contact detecting electrode functions as a ground electrode. This construction eliminates the need for disposing a ground electrode separately. Further, this construction can improve resistance to extraneous noises and hence can perform a more accurate detection.

Further, one or more embodiments of the present invention provide a construction in which the detection electrodes and the shield electrode are held by a non-conductive material and are integrally constructed. In this case, the relative positions of the respective electrodes are hard to change, so that the effects of changes in the capacitance caused by changes in the distances between the respective electrodes can be reduced and hence a more accurate detection can be performed.

Further, one or more embodiments of the present invention provide a construction in which the detection electrodes, the shield electrode, and the contact detecting electrode are held by a non-conductive material and are integrally constructed and can be deformed. In this case, the sensor can be easily handled and hence the work of mounting the sensor on a vehicle body or the like can be reduced.

According to one or more embodiments of the present invention, there is provided a capacitance sensor that effects an essential function as a proximity sensor (non-contact sensor) of a capacitance type and functions also as a touch sensor for detecting the contact of a man or an object.

### BRIEF DESCRIPTION OF THE DRAWINGS

FIG. 1A is an illustration showing the internal construction of a sensor body of a capacitance sensor, and FIG. 1B is an illustration showing an operating state of the sensor body.

FIG. 2A is a perspective view showing the entire sensor body, and FIG. 2B is a view showing the sensor body and its peripheral construction.

FIG. 3 is an illustration showing the internal construction and the mounting structure of the sensor body.

FIG. 4 is a perspective view showing a vehicle mounted with the sensor body.

FIG. 5 is a block diagram schematically showing a catch detecting device (including a detection circuit or the like) including a capacitance sensor.

FIG. 6 is a circuit diagram showing a specific example of a detection circuit (to a smoothing circuit).

FIG. 7 is a circuit diagram showing a specific example of the detection circuit (after the smoothing circuit) and a determination circuit.

FIG. 8 is a graph illustrating a proximity detection region and a touch detection region.

FIG. 9 is a timing chart showing the operation of the detection circuit.

FIGS. 10A and 10B illustrate graphs showing the data example illustrating the operation of the detection circuit.

### DESCRIPTION OF EMBODIMENTS

Hereinafter, the embodiments of the present invention will be described with reference to the drawings.

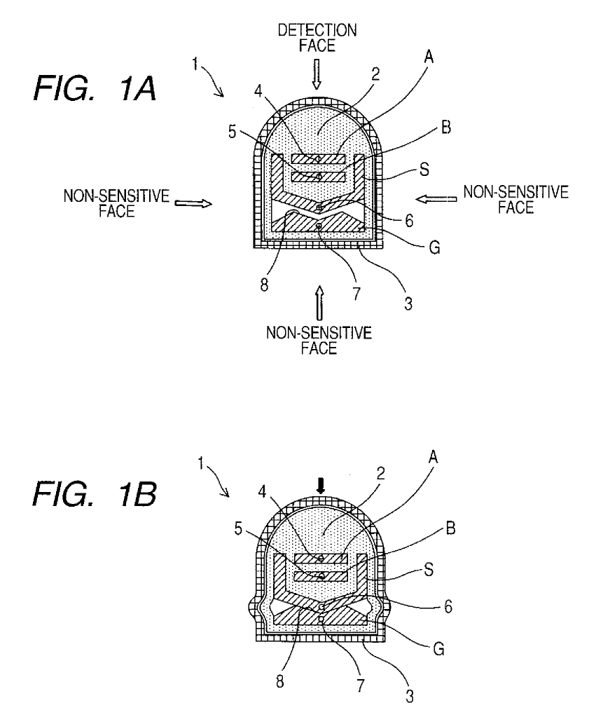

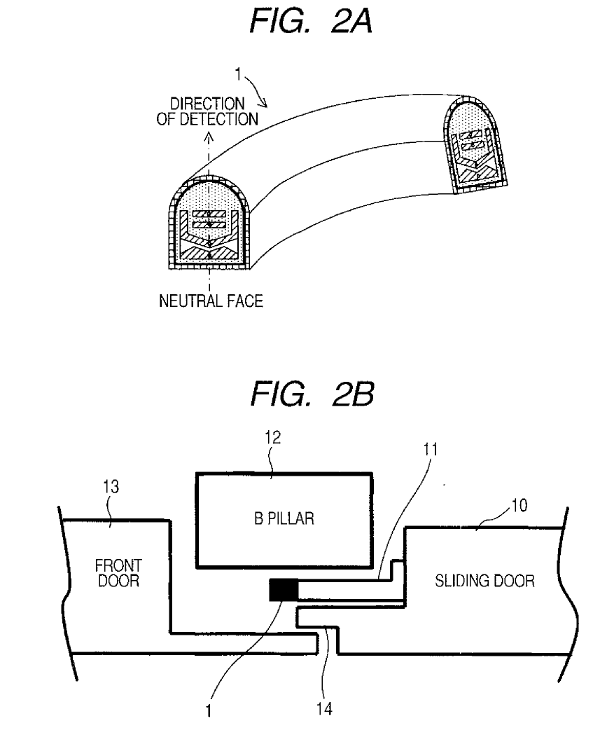

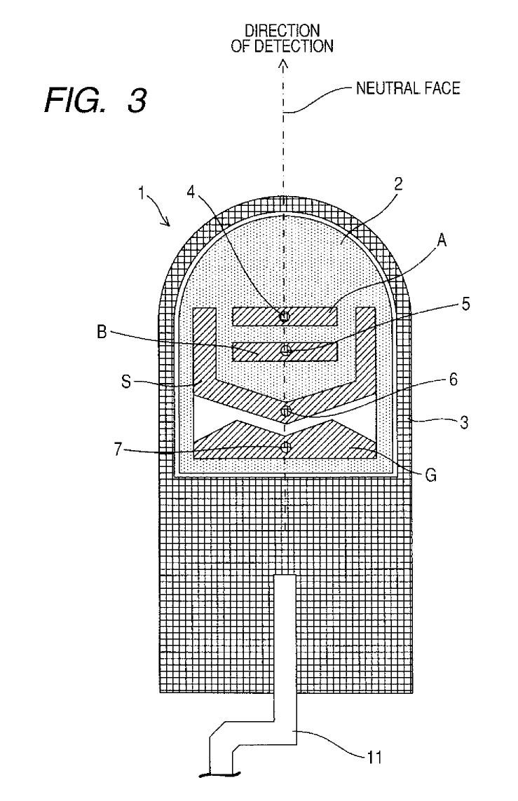

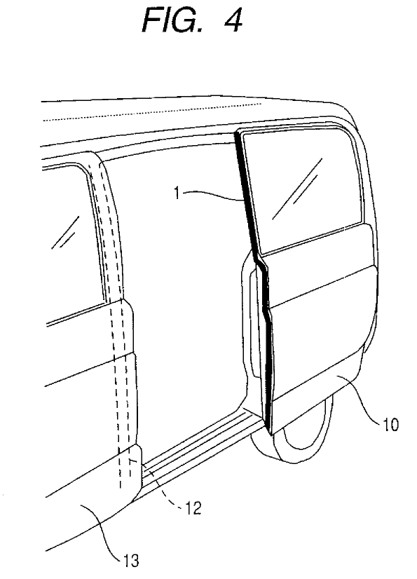

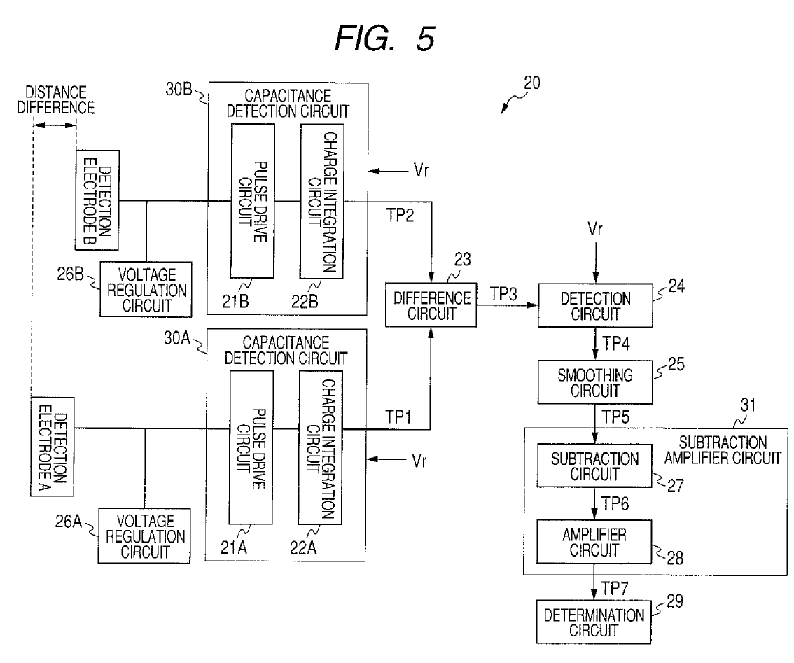

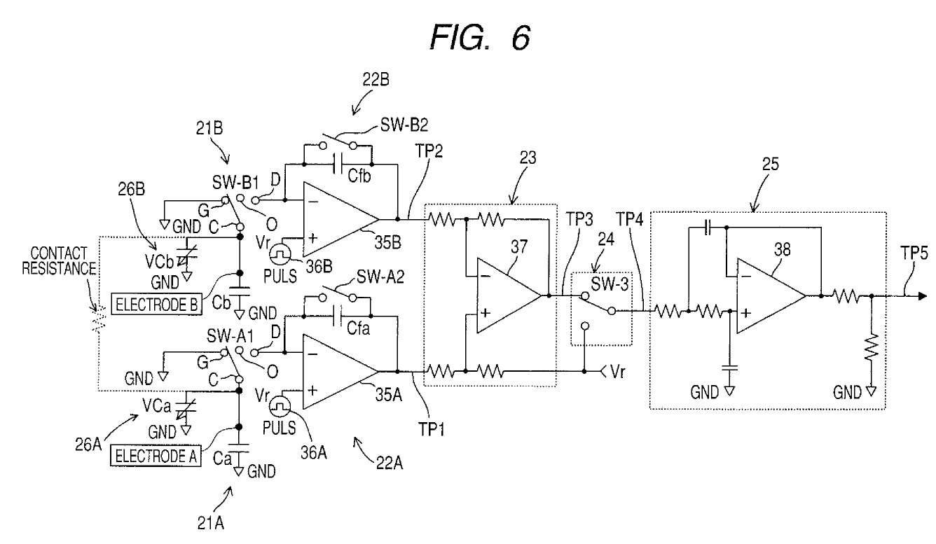

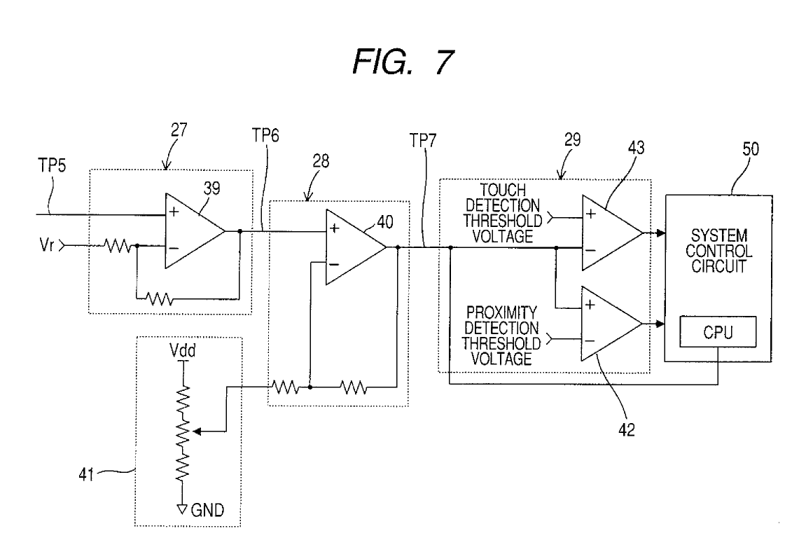

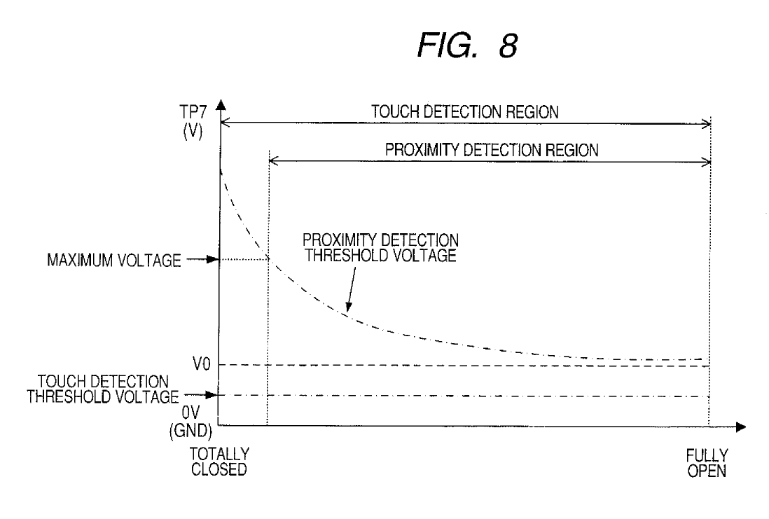

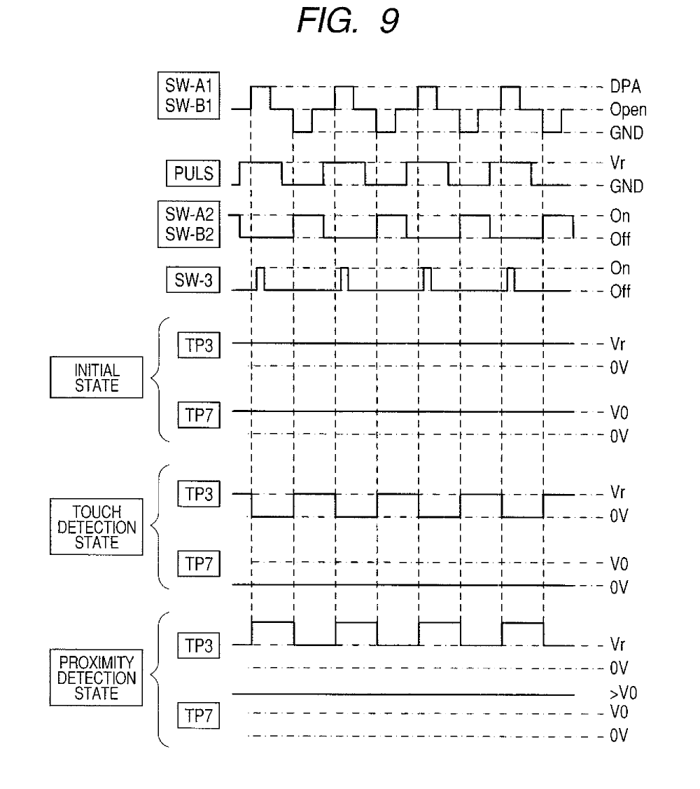

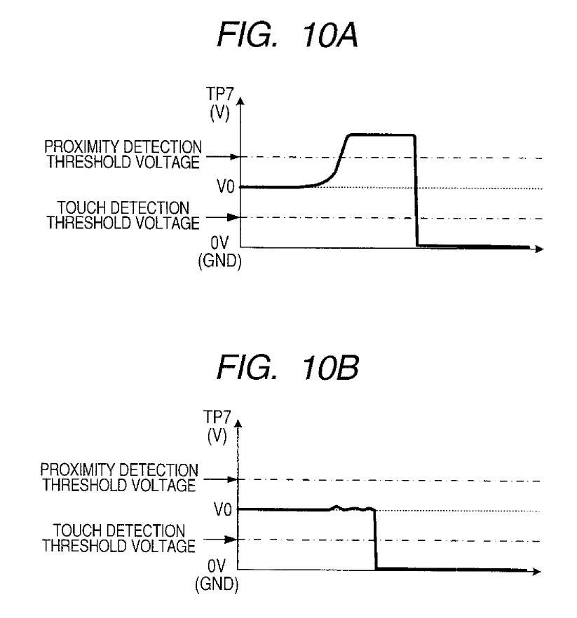

FIG. 1A is an illustration showing the internal construction of a sensor body 1 of a capacitance sensor, and FIG. 1B is an illustration showing an operating state as a touch sensor of the sensor body 1 (state in which the sensor is displaced by an object to be detected). Further, FIG. 2A is a perspective view showing the entire sensor body 1, and FIG. 2B is a horizontal sectional view showing the sensor body 1 placed on an automobile and its peripheral construction. FIG. 3 is an illustration showing the internal construction and the mounting structure of the sensor body 1. Still further, FIG. 4 is a perspective view showing an example in which the sensor body 1 is mounted on an automobile. Still further, FIG. 5 is a block diagram schematically showing a catch detecting device including a capacitance sensor according to one or more embodiments of the present invention (including a detection circuit and the like). Still further, FIG. 6 and FIG. 7 are circuit diagrams showing specific examples of a detection circuit 20 and the like of the capacitance sensor. Still further, FIG. 8 is a graph illustrating a proximity detection region and a touch detection region. Still further, FIG. 9 is a timing chart showing the operation of the detection circuit 20, and FIGS. 10A and 10B illustrate graphs illustrating the data example showing the operation of the detection circuit 20.

The sensor body 1, as shown in FIG. 1A, includes: a shield electrode S that is open on a detection face side and is formed nearly in the shape of a letter U in cross section; detection electrodes A, B disposed inside the shield electrode S; a ground electrode G disposed on the back side in the direction of detection of the shield electrode S and connected to the ground (also functions as a contact detecting electrode); a low dielectric insulating material 2 integrally connecting the respective electrodes (the respective detection electrodes A, B, the shield electrode S, and the ground electrode G); and a low dielectric insulating material 3 functioning as a cover covering the whole.

Further, as shown in FIG. 3, according to one or more embodiments of the present invention, the low dielectric insulating material 3 also functions as a member for fixing the sensor body 1 to a bracket 11 provided to a sliding door 10. For the detection electrode A, the detection electrode B, the shield electrode S, and the ground electrode G, an electrically conductive material can be used and hence these electrodes can be made of a metal plate or the like. These electrodes may be formed of an electrically conductive flexible material (material based on, for example, natural rubber, synthetic rubber, or elastomer and having appropriate flexibility and electric conductivity). The low dielectric insulating material 2 and the low dielectric insulating material 3 are preferably formed of an electrically non-conductive flexible material.

According to one or more embodiments of the present invention, the detection electrodes A, B, the shield electrode S, and the ground electrode C are integrally formed, but all of the electrodes need not be integrally formed. For example, only the detection electrodes A, B and the shield electrode S may be integrally formed and that the ground electrode G may be attached as a separate member to the automobile. Further, the detection electrodes A, B may be integrally formed; the shield electrode S and the ground electrode G may be integrally formed; and both members may be integrated with each other by the use of the low dielectric insulating material 3.

Conductor wires 4, 5, 6, and 7 made of material (for example, copper wire) having electric resistance smaller than the electrically conductive flexible material are disposed in the respective electrodes of this sensor body 1. Here, the positions where these conductor wires 4, 5, 6, and 7 are disposed are set near the neutral face (face on which a bending stress is brought to zero) of the sensor with respect to bending on a plane perpendicular to the direction of detection (up-and-down direction in FIGS. 1A and 1B).

Further, in the case of FIGS. 1A and 1B, the bottom surface of the shield electrode S is formed in the shape of a letter V slightly protruding down, and the top surface of the ground electrode G opposite to this has a depressed portion 8 formed in the shape of a letter V in such a way that the bottom surface of the shield electrode S can be fitted into the depressed portion 8.

Further, the low dielectric insulating material 2 is disposed in such a way as to cover the surrounding of the respective detection electrodes A, B and to close the space between the respective detection electrodes A and B and the space between the respective detection electrodes A, B and the shield electrode S. However, the low dielectric insulating material 2 is not disposed between the shield electrode S and the ground electrode G and a space is formed between them.

Here, the low dielectric insulating material 2 and the low dielectric insulating material 3 are made of electrically not-conductive flexible material (material based on, for example, natural rubber, synthetic rubber, or elastomer, and having appropriate flexibility and not having electric conductivity) and are made to have a low dielectric constant so as not to have a bad effect on a detecting operation as the capacitance sensor.

Further, as for the above-mentioned sensor body 1, for example, the respective flexible members (the shield electrode S, the detection electrodes A, B, the ground electrode G, and the low dielectric insulating material 2) except for the low dielectric insulating material 3 are integrally formed, and the low dielectric insulating material 3 (flexible material) is fitted on the formed product so as to cover the outer periphery of the formed product. In this manner, the sensor body 1 is manufactured as an integrated product.

Still further, the sensor body 1 is a body of a code type, as shown in FIG. 2A, and of a uniform cross section in which the respective flexible members and the respective conductor wires are disposed in a longitudinal direction. However, the sensor body 1 is not necessarily made of a long body but may be made of, for example, a short body that is short in the longitudinal direction (direction perpendicular to the cross section) as compared with the size of cross section.

The sensor body 1 constructed in this manner can be formed in a sufficiently small size, can have sufficient flexibility, and can be easily bent in the longitudinal direction. Thus, as shown in FIG. 3, it is sufficiently possible to dispose the sensor body 1 along the shape of the opening/closing edge portion of the sliding door 10. Further, by the shielding effect of the shield electrode S, the sensor body 1 has high sensitivity only on the detection face side (that is opposite to the edge portion of the sliding door 10 and is in a range in which an object may be caught by the sliding door 10) and the other faces do not detect an object (non-sensitive faces).

Here, the detection electrodes A, B are disposed at positions comparatively close to and far from the detection face, respectively. In this case, the detection electrode A corresponds to a main electrode and is disposed at a position close to an opening in the shield electrode S. On the other hand, the detection electrode B corresponds to a comparative electrode and is disposed at a position far from the opening in the shield electrode S and between the main electrode (detection electrode A) and the shield electrode S (position on the back side of the detection electrode A).

Further, the respective detection electrodes A and B, and the detection electrodes A, B and the shield electrode S, are always held in a separate state across a clearance because the low dielectric insulating material 2 is interposed therebetween. In particular, the detection electrodes A and B are disposed separately from each other so as to hold a specified distance difference in a direction opposite to the detection face and are disposed in a state not to be in contact with the shield electrode S (in other words, the low dielectric insulating material 2 connects and supports the respective electrodes in such a way that the respective electrodes are arranged in this manner).

The shield electrode S and the ground electrode G are disposed separately from each other in such a way as to maintain a specified distance difference in a direction opposite to the detection face in a natural state in which an external force is not applied to the sensor body 1 (in other words, the low dielectric insulating material 2 connects and supports the respective electrodes in such a way that the respective electrodes are arranged in this manner). When the detection face of the sensor body 1 is pressed by the contact of an object, as shown by an arrow in FIG. 1B, the detection electrodes A, B, the shield electrode S, and a pressed portion (a portion in the longitudinal direction) of the low dielectric insulating material 2 are deformed in such a way as to move to a back side (lower side in FIGS. 1A and 1B). With this, the bottom surface of the shield electrode S is fitted in and put into contact with the top surface of the ground electrode G to bring about an operating state in which only the shield electrode S and the ground electrode C are mutually brought into conduction. Here, even when the pressing force of the object is applied slantwise within a measure of range, the operating state is similarly brought about. Further, this operating state, as shown for example in FIG. 1B, is realized by forming the portions of the low dielectric insulating material 2 and the low dielectric insulating material 3 (in this case, both side portions located between the shield electrode S and the ground electrode G in the direction of detection) in a shape more easily deformed than the other portions and by deforming the portions in such a way as to protrude outside in the left-and-right direction, but the portions may also be deformed in such a way as to protrude inside. Examples of the shape more easily deformed include a shape in which a portion to be deformed is made thinner than the other portions and a shape in which a portion to be deformed is cut out, but it is not intended to limit the shape more easily deformed to these shapes.

Here, the sensor body 1, as shown in FIG. 2B, is mounted on the opening/closing edge portion of the sliding door 10 (rear door) in the vehicle via a bracket 11. FIG. 2B shows a state where the sliding door 10 is closed, and in this closed state the sliding door 10 is joined to a front door 13 with a small clearance between them in such a way as to sandwich a B pillar 12 (a pillar part on the vehicle body side located in the middle of the front door 13 and the sliding door 10). Further, a hem portion 14 protruding to the front door 13 is formed at the opening/closing edge portion of the sliding door 10, and the tip of this hem portion 14 is extended inside the front door 13 in the closed state, whereby the joint portion of the sliding door 10 and the front door 13 is closed with respect to the outside of the vehicle.

The sensor body 1 is disposed inside the hem portion 14 (inside the vehicle) and is fixed to the tip of the bracket 11 protruding to the front door 13, for example, by bonding in such a way that the detection face is located at a position further protruding to the front door 13 than the hem portion 14.

Here, in reality, as shown by a specific example in FIG. 3, a construction may be employed in which the low dielectric insulating material 3 (protecting cover) covering the periphery of the sensor body 1 functions as a part to be fixed to the bracket 11.

Further, the sensor body 1 and the peripheral portion of the sensor body 1 (the whole of the bracket 11 and the hem portion 14, or a portion on the sensor body 1 side of these parts) have, for example, a silicon tape placed on their surfaces, which makes their surfaces water repellent. In this respect, these members may be coated with a water repellent and/or may be coated with an oil repellent.

When the surfaces are made water repellent or oil repellent in this manner, it is hard for water droplets or oil droplets to adhere to the surfaces, and even if the water droplets or oil droplets adhere to the surfaces, they are easily diffused and flow down due to a water-repellent or oil-repellent effect and hence large water droplets or continuous water droplets that may cause a malfunction are not produced. Hence, this can significantly reduce the possibility that a malfunction will be caused by the water droplets or the like.

Next, a circuit section that is connected to the sensor body 1 and performs the processing of driving the sensor body 1 and a signal processing will be described.

This circuit section, as shown in FIG. 5 or FIGS. 6 and 7, includes: a pulse drive circuit 21A of the detection electrode A; a pulse drive circuit 21B of the detection electrode B; a charge integration circuit 22A of the detection electrode A; a charge integration circuit 22B of the detection electrode B; a difference circuit 23; a detection circuit 24; a smoothing circuit 25; a voltage regulation circuit 26A; a voltage regulation circuit 26B; a subtraction circuit 27; an amplifier circuit 28; and a determination circuit 29.

Here, the pulse drive circuit 21A and the charge integration circuit 22A construct a capacitance detection circuit 30A (capacitance detection circuit A) that converts floating capacitance constructed by the detection electrode A into voltage by a switched capacitor operation by using a voltage Vr as a reference voltage. Further, the pulse drive circuit 21B and the charge integration circuit 22B construct a capacitance detection circuit 30B (capacitance detection circuit B) that converts floating capacitance constructed by the detection electrode B into voltage by a switched capacitor operation by using the voltage Vr as the reference voltage. Still further, the subtraction circuit 27 and the amplifier circuit 28 construct a subtraction amplifier circuit 31.

In addition, in this case, the circuits to the amplifier circuit 28 construct the detection circuit 20 of the sensor and the output TP7 of the amplifier circuit 28 becomes a final sensor output. Here, the voltage Vr used as the reference voltage is a constant voltage (for example, 2.5 V) produced from a power source voltage (for example, 5 V) by a voltage divider circuit (not shown).

As shown in FIG. 6, the pulse drive circuit 21A is constructed of a switch SW-A1 that is driven by a drive circuit (not shown) to switch the connection of the detection electrode A at a high speed. The switch SW-A1 has a common terminal (C terminal), a grounded terminal (G terminal), an open terminal (O terminal), and a DPA terminal (D terminal), and the common terminal is connected to the detection electrode A, and the grounded terminal is connected to a vehicle ground (GND), and the DPA terminal is connected to the inverse input of an OP amplifier 35A to be described later. Further, as shown in the uppermost chart in FIG. 9, the switch SW-A1 is switched periodically at a high speed to a GND state in which the common terminal and the grounded terminal are brought into conduction, an Open state in which the common terminal and the open terminal are brought into conduction, and a DPA connection state in which the common terminal and the DPA terminal are brought into conduction. Here, capacitance shown by a reference sign Ca in FIG. 6 shows floating capacitance formed between the detection electrode A and the ground.

The pulse drive circuit 21B is constructed of a switch SW-B1 similar to the switch SW-A1 of the pulse drive circuit 21A. The switch SW-B1 has a common terminal (C terminal) connected to the detection electrode B, a grounded terminal (G terminal) connected to the vehicle ground, and a DPA terminal (D terminal) connected to the inverse input of an OP amplifier 35B to be described later. Further, the switch SW-B1, as shown in the uppermost chart in FIG. 9, operates in the same way as the switch SW-A1. Here, in FIG. 6, capacitance shown by a reference sign Cb shows floating capacitance formed between the detection electrode B and the ground.

The charge integration circuit 22A includes an OP amplifier (operational amplifier) 35A, a switch SW-A2 and a capacitor Cfa that construct a feedback circuit of the OP amplifier 35A, and a power circuit 36A for supplying a non-inverse input of the OP amplifier 35A with a pulse voltage (voltage value is a value equal to the voltage Vr).

Here, the capacitor Cfa is connected between the output TP1 of the OP amplifier 35A and the inverse input. Further, the switch SW-A2 is a switch that is connected in parallel to the capacitor Cfa and opens or closes both terminals of the capacitor Cfa (that is, the output and the inverse input of the OP amplifier 35A). Further, the switch SW-A2 is driven by a drive circuit (not shown), and as shown in the third chart from the top in FIG. 9, the switch SW-A2 is switched from an On state to an Off state at the timing when the switch SW-A1 is in an Open state before the switch SW-A1 being brought into a DPA connection state, and at the timing when the switch SW-A1 is switched from the Open state to the GND state, the switch SW-A2 is switched from the Off state to the On state.

Further, the output of the power circuit 36A is periodically changed as shown in the second chart from the top in FIG. 9. That is, at the timing when the switch SW-A2 is switched from the On state to the Off state, the output of the power circuit 36A is switched from the ground voltage to a charging voltage (voltage value is equal to the voltage Vr), and at the timing when the switch SW-A1 is switched from the DPA state to the Open state, the output of the power circuit 36A is switched from the charging voltage Vr to the ground voltage.

In this regard, although not shown in the drawing, the same pulse voltage (voltage value is equal to the voltage Vr) is supplied also to the shield electrode S in synchronization with the timing when the switches SW-A1, SW-A2 are switched. While the switches SW-A1, SW-A2 are connected to the DPA, the pulse voltage is supplied to the shield electrode S. With this, the shield electrode S is brought into the same potential as the detection electrodes A, B and hence charges are not charged or discharged between the shield electrode S and the detection electrodes A, B. From this, it can be considered that the capacitance between the shield electrode S and the detection electrodes A, B is equivalent to zero.

The charge integration circuit 22B, like the charge integration circuit 22A, includes an OP amplifier 35B, a switch SW-B2 and a capacitor Cfb that construct its feedback circuit, and a power circuit 36B for supplying a non-inverse input of the OP amplifier 35B with a pulse voltage.

Here, the capacitor Cfb is connected between the output TP2 of the OP amplifier 35B and the inverse input. Further, the switch SW-B2 is a switch that is connected in parallel to the capacitor Cfb and opens or closes both terminals of the capacitor Cfb (that is, the output and the inverse input of the OP amplifier 35B). Further, the switch SW-B2, as shown in the third chart from the top in FIG. 9, is operated in the same way as the switch SW-A1. Further, the output of the power circuit 36B, like the power circuit 36A, is changed as shown in the second chart from the top in FIG. 9.

The difference circuit 23, as shown in FIG. 6, is a circuit that is constructed of an OP amplifier 37 and resistances (whose signs are omitted) and computes and outputs the difference between the output TP1 of the OP amplifier 35A (the output of the capacitance detection circuit A) and the output TP2 of the OP amplifier 35B (the output of the capacitance detection circuit B). This difference circuit 23 uses the above-mentioned voltage Vr as the reference voltage, so that when there is no difference between the output TP1 and the output TP2, the output TP3 of the difference circuit 23 becomes the reference voltage Vr.

The detection circuit 24 is a synchronization detection circuit for extracting a signal voltage TP4 from the output TP3 of the difference circuit 23 by using the voltage Vr as the reference voltage. This detection circuit 24 is constructed of a switch SW-3 (turned on at the timing when current is passed through the respective detection electrodes) driven in the manner shown in the fourth chart from the top in FIG. 9.

The smoothing circuit 25, as shown in FIG. 6, is an integration circuit that is constructed of an OP amplifier 38, and resistances and capacitances (whose signs are omitted) and functions as an LPF (Low Pass Filter) and removes useless high-frequency components from the output TP4 of the detection circuit 24 to smooth the output TP4.

Further, the voltage regulation circuits 26A, 26B, as shown in FIG. 6, are constructed of variable capacitors VCa, VCb connected between the respective detection electrodes A, B and the ground, respectively. The values of these variable capacitors VCa, VCb are previously set in such a way that the output voltages TP1, TP2 of the respective capacitance detection circuits A, B in a non-detection state where an object to be detected such as a man does not exist in the direction of detection are equal to each other.

When these voltage regulation circuits 26A, 26B are not provided, the detection electrode A is disposed close to the detection face and a large amount of charges are emitted, so that the output voltage TP1 becomes larger than the output voltage TP2 even in a non-detection state. Thus, these voltage regulation circuits 26A, 26B are provided and the variable capacitors are set to VCa<VCb, whereby the output voltages TP1, TP2 are regulated so as to become equal to each other in the non-detection state.

Next, the subtraction circuit 27, as shown in FIG. 7, is a circuit that is constructed of an OP amplifier 39 and resistances (whose signs are not shown) and subtracts a value corresponding to the voltage Vr from the output TP5 of the smoothing circuit 25 and amplifies (pre-amplifies) the subtraction result.

Further, the amplifier circuit 28, as shown in FIG. 7, is a circuit that is constructed of an OP amplifier 40 and resistances (whose signs are not shown) and subtracts a value corresponding to an offset voltage from the output TP6 of the subtraction circuit 27 and amplifies (finally amplifies) the subtraction result. The offset voltage is produced by, for example, an offset voltage regulation circuit 41 (whose output voltage is variable) shown in FIG. 7. This offset voltage regulation circuit 41 may be a simple voltage divider circuit (whose output voltage is constant).

According to one or more embodiments of the present invention, the output of the amplifier circuit 28 (output of the OP amplifier 40) becomes a sensor output TP7. Further, the offset voltage is used for regulating the final sensor output TP7 to a specified level corresponding to the determination circuit 29. The offset voltage is set in such a way that, for example, when the output of the smoothing circuit TP5 is the voltage Vr (for example, 2.5 V) in the non-detection state, the sensor output TP7 becomes a specified initial value V0 (for example, 1V).

In the capacitance sensor including the detection circuit constructed in the manner described above, in the non-detection state, the output voltages TP1, TP2 of the respective capacitance detection circuits 30A, 30B are made equal to each other by the effects of the voltage regulation circuits 26A, 26B, so that as shown by the “initial state” chart in FIG. 9, the outputs of the sensor (outputs TP3 to TP7) become values corresponding to the reference voltage Vr and the final sensor output TP7 becomes the initial value V0 (for example, 1 V) in this case. When an object (dielectric object) approaches the detection face, the output voltage TP1 of the capacitance detection circuit 30A becomes larger than the output voltage TP2 of the capacitance detection circuit 30B because the detection electrodes A, B have a distance difference with respect to the detection face. As a result as shown by the “proximity detection state” chart in FIG. 9, the sensor output TP7 increases and becomes significantly larger than the initial value V0 corresponding to the reference voltage Vr. Further, when the object (dielectric object or non-dielectric object) is put into contact with the detection face to bring about a state in which the shield electrode S and the ground electrode G are brought into conduction, the drive potential of the shield electrode S is lowered. When the detection electrode A, the detection electrode B, and the shield electrode S are driven by the same phase and same potential, coupling capacitance is not produced between the respective electrodes. However, when the drive voltage of the shield electrode S is lowered, drive potential differences are developed respectively between the detection electrode A and the shield electrode S and between the detection electrode B and the shield electrode S. With this, the output of the capacitance detection circuit A and the output of the capacitance detection circuit B are saturated and hence a difference in their outputs is brought to nearly zero, whereby the sensor output TP7 is decreased from the initial value V0 to nearly zero.

For this reason, the capacitance sensor according to one or more embodiments of the present invention functions also as a touch sensor for detecting the contact of an object. Here, the capacitance sensor according to one or more embodiments of the present invention uses the output TP7 of the same detection circuit as a common sensor output to the approach and contact of the object, and this sensor output TP7 is basically changed in opposite directions by the approach and contact of the object, whereby the approach or contact of the object can be detected. Thus, the capacitance sensor according to one or more embodiments of the present invention has an excellent feature capable of detecting the approach and contact of the object in real time and continuously without switching the detection circuit and the signal processing.

In this regard, FIG. 10A is a data example showing a change in the sensor output TP7 when a dielectric object approaches the sensor body 1. When the dielectric object approaches the sensor body 1, as described above, the sensor output TP7 increases, and when the sensor output TP7 becomes larger than a proximity detection threshold voltage, the sensor body 1 is brought into a proximity detection state. When the dielectric object further moves to the detection face of the sensor body 1 and comes into contact with the detection face to bring the shield electrode S and the ground electrode G into conduction, the sensor output TP7 decreases instantaneously and becomes nearly zero V and becomes smaller than a touch detection threshold voltage, so that the sensor body 1 is brought into a touch detection state. In this manner, according to this sensor, the approach and contact of an object (dielectric object) can be detected in real time and continuously.

Further, FIG. 10B is a data example showing a change in the sensor output TP7 when a non-dielectric object approaches the sensor body 1. When the non-dielectric object approaches the sensor body 1, the capacitance is not changed and hence the sensor output TP7 is held at the value V0 corresponding to the reference voltage, so that the sensor body 1 is not brought into a proximity detection state. However, when the non-dielectric object further moves to the detection face of the sensor body 1 and comes into contact with the detection face to bring the shield electrode S and the ground electrode G into conduction, the sensor output TP7 decreases instantaneously and becomes nearly zero V and becomes smaller than the touch detection threshold voltage, so that the sensor body 1 is brought into the touch detection state. In this manner, according to this sensor, the approach and contact of an object (non-dielectric object) can be detected in real time.

Further, the capacitance sensor according to one or more embodiments of the present invention has the same fundamental principle as the capacitance sensor (proximity sensor) as proposed in JP-A-2002-373729. Thus, the capacitance sensor according to one or more embodiments of the present invention can make a proximity detection with a small number of malfunctions within a spatially opened detection region without being affected by surrounding objects (in other words, it can highly effect also an essential function as the proximity sensor).

Still further, the capacitance sensor according to one or more embodiments of the present invention includes the amplifier circuit 28, which subtracts a value corresponding to the voltage Vr from the output of the smoothing circuit 25 and amplifies the subtraction result, and outputs the output of this amplifier circuit 28 as the sensor output. For this reason, only a change caused by the approach or contact of the object can be taken out before amplification and hence the range of a change in the output signal can be limited to a minimum necessary amount, so that the handling of the senor output (the above-mentioned signal amplification and offset processing in the downstream of the smoothing circuit, or the determination processing to be described below) becomes easy.

Next, the determination circuit 29 will be described in accordance with one or more embodiments of the present invention.

The determination circuit 29 is a circuit which determines that the object (dielectric object) approaches the detection face on the basis of the fact that the sensor output TP7 changes in an increase direction from the initial value V0 (for example, 1 V) in the non-detection state and which determines that the object (dielectric object and non-dielectric object) comes into contact with the detection face on the basis of the fact that the sensor output TP7 changes in an decrease direction from the initial value V0. In this case, the determination circuit 29 is constructed of comparators 42, 43. The comparator 42 is a circuit that compares the sensor output TP7 with a proximity detection threshold voltage (for example, 1.2 V or more) and produces an output (proximity detection output) when the sensor output TP7 increases and becomes larger than the proximity detection threshold voltage. On the other hand, comparator 43 is a circuit that compares the sensor output TP7 with a touch detection threshold voltage (for example, 0.5 V) and produces an output (touch detection output) when the sensor output TP7 decreases and becomes smaller than the touch detection threshold voltage. Here, the touch detection threshold voltage may be set to an arbitrary value within a range from 0 V to a value smaller than the initial value V0. However, the proximity detection threshold voltage, for example like the above-mentioned patent document 3, may be changed in accordance with a door position on the basis of learned data in consideration of the effect of the surrounding members near the totally closed position. In this case, as shown in FIG. 8, when the door approaches the totally closed position, a change in the sensor output caused by the vehicle body such as a B pillar becomes large, so that it is difficult to discriminate between the change and a small change in the sensor output caused when a finger or the like approaches. Thus, when the door approaches the totally closed position, the proximity detection is not performed.

The determination results (proximity detection output and touch detection output) of the determination circuit 29 are used, for example, in the following manner in a control circuit 50 of an electrically operated sliding door. That is, in a proximity detection region in which the proximity detection as the capacitance type proximity sensor can be performed without any problem (for example, as shown in FIG. 8, a range in which the sensor output is not saturated, or a more limited range in which a false detection is not caused by mechanical backlash and play, or the like), when the proximity detection output is produced, it is determined that something is caught (or something is likely to be caught) and the operation of preventing something from being caught is performed. Further, as shown in FIG. 8, when the touch detection output is produced in the entire range including the proximity detection region, it is determined that something is caught (or something is likely to be caught) and the operation of preventing something from being caught is performed.

In this regard, the signal (digitalized by a D/A converter (not shown)) of the sensor output TP7 may be input to a microcomputer including the CPU of the control circuit 50, and may be used for the control processing of the control circuit 50.

According to a catch detecting device that is constructed of the above-mentioned capacitance sensor, the following effects can be produced.
(1) A detection area can be arranged in such a way as to extend along the curved opening/closing edge portion of the vehicle door (that is, a non-sensitive area can be eliminated), and directivity can be limited to only a direction to come near to the opening/closing edge portion by the shield electrode S, so that the possibility of a malfunction can be decreased.
(2) Further, this sensor has the entire sensor body, which includes the detection electrodes, the shield electrode, and the ground electrode, constructed of flexible material and hence has flexibility as the whole. For this reason, the sensor body is not necessarily formed in advance in a shape curved in accordance with the shape of a portion (edge of the door) to which the sensor is attached, but can be attached adaptively to the portion, to which the sensor is attached and which can be formed in various shapes, with flexibility at the site of construction (on-site attachment). This allows the shared use of parts and can improve the productivity of product (in this case, vehicle) to which this sensor is attached.
(3) In the proximity detection region, the dielectric object to be detected such as a human body can be detected on a noncontact basis, so that it is possible to determine early that the object is caught or is likely to be caught and to perform the operation of preventing the object from being caught (the operation of stopping the operation of closing an opening/closing body or further the operation of opening the opening/closing body by a specified amount) with almost no catching load caused to the object.
(4) The capacitance sensor of a differential charge transfer type is used, so that it is possible to perform a noise-resistant highly sensitive detection.
(5) In the state in which a proximity sensor of a capacitance type can perform an excellent detection (state in which the sliding door is located in the proximity detection region), for example, when the determination circuit 29 determines that an object approaches (a proximity detection output is produced), if the control circuit 50 is configured to determine that the object is caught and to perform the operation of preventing the object from being caught the catch prevention operation can be performed earlier and at a lower load than the related-art detection device using a pressure-sensitive switch. Further, for example, in the entire range, when the determination circuit 29 determines that an object comes in contact (when the touch detection output is produced), if the control circuit 50 is configured to determine surely that the object is caught and to perform the catch prevention operation, even in the state in which it is difficult for the proximity sensor of a capacitance type to perform an excellent detection (state in which the sliding door is located outside the proximity detection region), the touch detection makes it possible to realize the operation of preventing the object from being caught in an appropriate manner without a malfunction. Further, even if the object is a low dielectric object such as a plastic object, the touch detection makes it possible to surely detect the object and to perform the operation of preventing the object from being caught. In other words, with a device that uses the sensor according to one or more embodiments of the present invention and detects an object being caught in an opening/closing body, it is possible to realize a catch detecting device that has the advantage of a touch sensor system and the advantage of a capacitance type proximity sensor system and has as a simple construction as the capacitance type proximity sensor system.
(6) Further, this sensor has a construction in which when the sensor is pressed and deformed in the direction of detection by the contact of an object, the sensor has its shield electrode S and ground electrode G brought into contact with each other and hence can detect the object. With this, the sensor can detect the contact of the object and hence can improve the reliability of detection of a broken wire. This is because, for example, even if the detection electrode A or the detection electrode B causes a break in a wire, the sensor can detect the contact of the object by the contact of the shield electrode S and the ground electrode G.
(7) Still further, the conductor wires 4, 5, 6, and 7 made of material having smaller electric resistance than the flexible material constructing the respective electrodes are disposed along the longitudinal direction of the sensor in the respective detection electrodes A, B, the ground electrode G, and the shield electrode S, and the positions where these conductor wires are disposed are set near the neutral face of the sensor with respect to bending on a plane perpendicular to the direction of detection. For this reason, firstly, the resistance distribution of the respective electrodes can be reduced. Generally, since the conductive material such as conductive rubber is higher in resistance value than a metal conductor wire, in the case of modulated electric drive, the waveform is smoothed by the effect of the resistance value and hence detection performance differs between at a position close to a power supply and at a position far from the power supply. In particular, when the conductor wire becomes long, this bad effect becomes serious. However, if the conductor wires are disposed in the manner described above, there is provided the advantage of reducing the resistance value as a whole and eliminating such a bad effect. Secondly, there is provided the advantage of facilitating the connection of a cable for supplying the power or taking out the signal (connection to the detection circuit side) by means of the conductor wires.

Moreover, since the conductor wires are disposed near the neutral face, the following effects are produced. That is, even if the conductor wires are made of material not having sufficient elasticity, the stress applied to the conductor wires by the bending becomes zero or small, so that it is possible to keep the feature of this sensor such that the bending can be performed without stress and hence the easiness of attaching the sensor in a curved state in accordance with the shape of the door edge or the like can be maintained sufficiently.
(8) Still further, the sensor according to one or more embodiments of the present invention has its surface subjected to the water repellent processing or the oil repellent processing. Thus, the sensor can produce the effect of reducing the possibility that a malfunction will be caused by water or oil. According to the research conducted by the inventors, for example, when the capacitance sensor (sensor body portion except for the detection circuit) has water droplets or the like continuously stuck to its detection face in the manner crossing the detection face, the capacitance sensor develops a phenomenon such that although an object (dielectric object) does not approach the sensor, the output of the sensor changes, which results in making a false determination that the object approaches. However, according to one or more embodiments of the present invention, the droplets or the like can be prevented from being continuously stuck and hence such a malfunction is hardly caused.
(9) Still further, the sensor according to one or more embodiments of the present invention has the low dielectric insulating material 2 interposed between the respective detection electrodes A and B and between the respective detection electrodes A, B and the shield electrode S (construction such that no space is disposed between the respective detection electrodes A and B and between the respective detection electrodes A, B and the shield electrode S). For this reason, as compared with a construction in which spaces are disposed between the respective detection electrodes A and B and between the respective detection electrodes A , B and the shield electrode S so as to put the respective detection electrodes A and B or the respective detection electrodes A, B and the shield electrode S into contact with each other to detect the contact of an object, the sensor according to one or more embodiments of the present invention can provide the following advantage.

That is, when the spaces are disposed between the electrodes as described above, the clearance between the respective detection electrodes A and B and the clearances between the respective detection electrodes A, B and the shield electrode S are changed with time by the deformation of long duration (permanent deformation) or the like of the electrodes, and hence performance (detection capability as the capacitance sensor) is likely to be changed. Moreover, there is presented the problem that a foreign matter or moisture (water) is likely to intrude between the respective detection electrodes A and B and between the respective detection electrodes A, B and the shield electrode S and again is likely to change the detection capability as the capacitance sensor.

However, the sensor according to one or more embodiments of the present invention does not have the above-mentioned space and hence can eliminate the above-mentioned deformation of long duration and the intrusion of the foreign matter or the like. Hence, the sensor according to one or more embodiments of the present invention provides the advantage of surely preventing the above-mentioned problem.

1. A code-type sensor for detecting a change in capacitance, comprising:
a plurality of detection electrodes for detecting a change in capacitance;
a shield electrode surrounding the plurality of detection electrodes so as to restrict a detection range of the capacitance and having an opening in a direction of detection; and
a contact detecting electrode for detecting contact disposed along a longitudinal direction of the sensor, wherein
the detection electrodes are disposed at a position close to the opening in the shield electrode and at a position far from the opening in the shield electrode,
the contact detecting electrode is disposed on a back side in the direction of detection of the shield electrode, and
the respective detection electrodes are integrally connected to each other in such a way as to be held in a separate state, the detection electrodes and the shield electrode are integrally connected to each other in such a way as to be held in a separate state, and the shield electrode and the contact detecting electrode are kept in such a way as to be held in a separate state across a clearance in a natural state and are brought into contact with each other when the sensor is pressed in the direction of detection by contact of an object.

2. The capacitance sensor as claimed in claim 1, wherein the contact detecting electrode functions as a ground electrode.

3. The capacitance sensor as claimed in claim 1, wherein the detection electrodes and the shield electrode are held by a non-conductive material and are integrally constructed.

4. The capacitance sensor as claimed in claim 1, wherein the detection electrodes, the shield electrode, and the contact detecting electrode are held by a non-conductive material and are integrally constructed and are constructed in such a way as to be deformed.

5. The capacitance sensor as claimed in claim 2, wherein the detection electrodes and the shield electrode are held by a non-conductive material and are integrally constructed.

6. The capacitance sensor as claimed in claim 2, wherein the detection electrodes, the shield electrode, and the contact detecting electrode are held by a non-conductive material and are integrally constructed and are constructed in such a way as to be deformed.
